(19) United States
(12) Patent Application Publication
(10) Pub. No.: US 2023/0345743 A1
(43) Pub. Date: Oct. 26, 2023

(54) MULTILAYER JUNCTION PHOTOELECTRIC CONVERSION ELEMENT AND METHOD FOR MANUFACTURING THE SAME

(71) Applicants: KABUSHIKI KAISHA TOSHIBA, Tokyo (JP); TOSHIBA ENERGY SYSTEMS & SOLUTIONS CORPORATION, Kawasaki-shi Kanagawa (JP)

(72) Inventors: TAKESHI GOTANDA, Yokohama Kanagawa (JP); TOMOHIRO TOBARI, Yokohama Kanagawa (JP); YUTAKA SAITA, Yokohama Kanagawa (JP)

(73) Assignees: KABUSHIKI KAISHA TOSHIBA, Tokyo (JP); TOSHIBA ENERGY SYSTEMS & SOLUTIONS CORPORATION, Kawasaki-shi Kanagawa (JP)

(21) Appl. No.: 18/314,412

(22) Filed: May 9, 2023

Related U.S. Application Data
(63) Continuation of application No. PCT/JP2020/041884, filed on Nov. 10, 2020.

(51) Int. Cl. H10K 30/20; H10K 71/60; H10K 30/57; H10K 30/86

(52) U.S. Cl. CPC H10K 30/211; H10K 71/60; H10K 30/57; H10K 30/86; H10K 30/85

(57) ABSTRACT

Provided is a semiconductor element that can generate power with high efficiency and has high durability.

A multilayer junction photoelectric conversion element according to an embodiment includes:
a first electrode;
a first photoactive layer including a perovskite semiconductor;
a first doped layer;
a tunnel insulating film;
a second photoactive layer containing silicon; and
a second electrode,
in this order. A thickness of the tunnel insulating film is 1 nm to 15 nm, and the first doped layer contains silicon and a trivalent or pentavalent element as an impurity. The element can be manufactured by a method including forming a bottom cell including a second active layer and then forming a first photoactive layer by coating.

### CROSS REFERENCE TO RELATED APPLICATIONS

This application is based upon and claims the benefit of priority from the prior International Patent Application PCT/JP2020/041884, filed on Nov. 10, 2020, the entire contents of which are incorporated herein by reference.

### FIELD

Embodiments of the present invention relate to a multilayer junction photoelectric conversion element having high efficiency, a large area, and high durability, and a method for manufacturing the same.

### BACKGROUND

Conventionally, a semiconductor element such as a photoelectric conversion element and a light-emitting element have been generally manufactured by a relatively complicated method such as a chemical vapor deposition method (CVD method). However, when the semiconductor element can be manufactured by a simpler method, for example, a coating method, a printing method, or a physical vapor deposition method (PVD method), the semiconductor elements can be easily manufactured at low cost, and thus a method for manufacturing a semiconductor element by such a method is being sought.

Meanwhile, a semiconductor element made of an organic material or a combination of an organic material and an inorganic material, such as a solar cell, a sensor, and a light-emitting element, has been actively researched and developed. These researches aim to find an element having high photoelectric conversion efficiency. Furthermore, as an object of such research, an element using a perovskite semiconductor can be manufactured by a coating method or the like, and high efficiency can be expected, and thus, the element has recently attracted attention.

### BRIEF DESCRIPTION OF THE DRAWINGS

FIG. 1 is a conceptual diagram illustrating a structure of a multilayer junction photoelectric conversion element according to an embodiment of the present invention.

FIG. 2 is a conceptual diagram illustrating a structure of a multilayer junction photoelectric conversion element according to Comparative Example 1.

FIG. 3 is a conceptual diagram illustrating a structure of a multilayer junction photoelectric conversion element according to Example 2.

### DETAILED DESCRIPTION

Embodiments will now be explained with reference to the accompanying drawings.

According to an embodiment, there is provided a multilayer junction photoelectric conversion element including:
a first electrode;
a first photoactive layer including a perovskite semiconductor;
a first doped layer;
a tunnel insulating film;
a second photoactive layer containing silicon; and
a second electrode,
in this order,
in which a thickness of the tunnel insulating film is 1 nm to 15 nm, and
the first doped layer contains silicon and a trivalent or pentavalent element as an impurity.

In addition, according to another embodiment, there is provided a method for manufacturing a multilayer junction photoelectric conversion element, the method including the steps of:
(a) forming a second metal electrode on one surface of a silicon wafer constituting a second photoactive layer;
(b) forming a tunnel insulating film on a back surface of the silicon wafer on which a second electrode is formed;
(c) forming a first doped layer on the tunnel insulating film;
(d) forming a first photoactive layer containing perovskite on the first doped layer by a coating method; and
(e) forming a first electrode on the first photoactive layer.

In an embodiment, a photoelectric conversion element means both an element that converts light into electricity such as a solar cell and a sensor and an element that converts electricity into light. The both elements are different in whether an active layer functions as a power generation layer or as a light emitting layer, but are the same in basic structure.

Hereinafter, constituent members of a multilayer junction photoelectric conversion element according to the embodiment will be described using a solar cell as an example, but the embodiment can also be applied to other photoelectric conversion elements having a common structure.

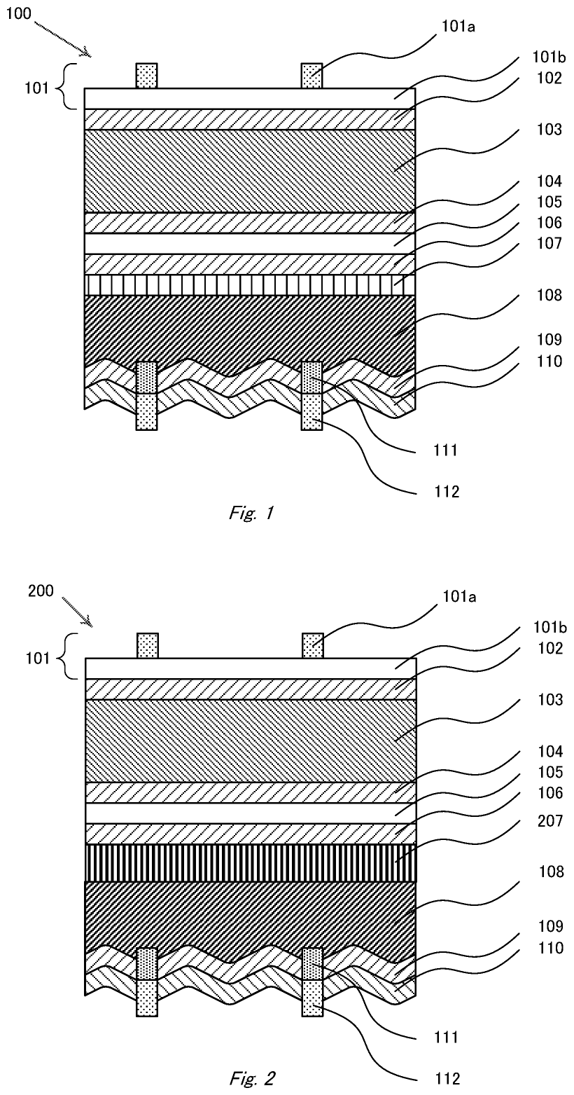

FIG. 1 is a schematic diagram illustrating an example of a configuration of a solar cell which is an aspect of a multilayer junction photoelectric conversion element according to an embodiment.

In FIG. 1, a first electrode 101 and a second electrode 112 serve as an anode or a cathode, and electric energy generated by the element is extracted therefrom. The photoelectric conversion element according to the embodiment includes a first photoactive layer 103 containing a perovskite semiconductor, a first doped layer 106 having semiconductor characteristics, a tunnel insulating film 107, and a second photoactive layer 108 containing silicon in this order between the first electrode 101 and the second electrode 112.

In the solar cell, the first photoactive layer 103 and the second photoactive layer 108 are layers containing a material that is excited by incident light and generates electrons or holes in the first electrode 101 and the second electrode 112. When the element according to the embodiment is a light-emitting element, each photoactive layer is a layer containing a material that generates light when electrons and holes are injected from the first electrode and the second electrode.

In addition, in the element illustrated in FIG. 1, a first buffer layer 102 is disposed between the first electrode and the first photoactive layer, a second buffer layer 104 and an intermediate transparent electrode 105 are disposed between the first photoactive layer 103 and the first doped layer 106, and a third doped layer 111 is disposed between the second photoactive layer and the second electrode 112. In addition, a second doped layer 109 and a passivation film 110 are disposed on a back side surface of the second photoactive layer. The element according to the embodiment preferably includes these layers or films.

Hereinafter, each layer constituting the semiconductor element according to the embodiment will be described.

(First Electrode)

In the present embodiment, the first electrode 101 is disposed on a light incident surface side.

In FIG. 1, the first electrode 101 is a composite of a first metal electrode 101a and a first transparent electrode 101b. Since the metal electrode and the transparent electrode have different characteristics, either one of them may be used or a combination thereof may be used depending on the characteristics.

The metal electrode can be selected from any conventionally known metal electrodes as long as the metal electrode has conductivity. Specifically, a conductive material such as gold, silver, copper, platinum, aluminum, titanium, iron, or palladium can be used.

The first metal electrode can be formed by any method. For example, it can be formed by applying a paste composition containing a metal material onto a base material or a film and then performing a heat treatment. The metal electrode can also be formed by physical vapor deposition (PVD) using a mask pattern. Furthermore, a vacuum heating vapor deposition method, an electron beam vapor deposition method, a resistance heating vapor deposition method, or the like can be used. According to these methods, the underlying layer, for example, the perovskite semiconductor layer is less damaged than sputter deposition or the like, so that the conversion efficiency and durability of the solar cell can be improved. A screen printing method using a metal paste is also preferable. The metal paste may contain glass frit or an organic solvent. In addition, light induced plating (LIP) can be used. LIP is a method in which an electrode can be selectively formed in a portion where silicon is exposed. In this case, Ni, Ag, Cu, or the like can be used as the plating metal.

The first electrode is generally formed, after forming a laminate of the other layers, on the laminate, for example, on the first buffer layer. For example, it can be formed by applying a paste composition containing a metal as described above and heating the paste composition. When the treatment involving heating is performed as described above, the temperature is preferably lower than the annealing temperature of the perovskite-containing active layer described later. Specifically, it is more preferable to control the temperature of the first photoactive layer to a range of 50 to 150° C. Even in a case where a high-temperature furnace or a heat source is used for formation of the first electrode, it is possible to perform control by controlling the temperature of the element, bringing a surface different from an electrode-formed surface into contact with a stage having a cooling mechanism, or making the atmosphere vacuum. Further, this heating step can be performed simultaneously with the heating step in the formation of the second electrode described later. That is, heating in the step of manufacturing the first metal electrode and the second electrode can be performed simultaneously.

In general, the first metal electrode has a shape in which a plurality of metal wires are arranged substantially in parallel. A thickness of the first metal electrode is preferably 30 to 300 nm, and the width is preferably 10 to 1000 μm. When the thickness of the metal electrode is less than 30 nm, conductivity tends to decrease and resistance tends to increase. An increase in resistance may cause a decrease in photoelectric conversion efficiency. When the thickness of the metal electrode is 100 nm or less, the metal electrode has light transmissivity, so that power generation efficiency and light emission efficiency can be improved, which is preferable. A sheet resistance of the metal electrode is preferably as low as possible, and is preferably 10 Ω/sq. or less. The metal electrode may have a single-layer structure or a multilayer structure in which layers made of different materials are laminated.

Meanwhile, when the thickness is large, it takes a long time to form a film of the electrode, so that productivity is deteriorated, and at the same time, the temperature of other layers is increased and damages occur, and the performance of the solar cell may be deteriorated.

The first transparent electrode 101b is a transparent or translucent conductive layer. The first electrode 101b may have a structure in which a plurality of materials are laminated. In addition, since the transparent electrode transmits light, the transparent electrode can be formed on the entire surface of the laminate.

Examples of the material of such a transparent electrode include a conductive metal oxide film and a translucent metal thin film. Specifically, a film (NESA or the like) produced using a conductive glass is used such as: indium oxide, zinc oxide, and tin oxide; indium-soot oxide (ITO), indium-zinc-oxide (IZO), fluorine-doped tin oxide (FTO), and indium zinc-oxide, which are composites of indium oxide, zinc oxide and tin oxide; and aluminum, gold, platinum, silver, copper. In particular, metal oxides such as ITO or IZO are preferred. The transparent electrode made of such a metal oxide can be formed by a generally known method. Specifically, the transparent electrode is formed by sputtering in an atmosphere rich in a reaction gas such as oxygen.

The thickness of the first transparent electrode is preferably 30 to 300 nm when the material of the electrode is ITO. When the thickness of the electrode is less than 30 nm, conductivity tends to decrease and resistance tends to increase. An increase in resistance may cause a decrease in photoelectric conversion efficiency. Meanwhile, when the thickness of the electrode is larger than 300 nm, flexibility of the ITO film tends to decrease. As a result, in a case where the thickness is large, cracking may occur when stress acts. A sheet resistance of the electrode is preferably as low as possible, and is preferably 10 Ω/sq. or less. The electrode may have a single-layer structure or a multilayer structure in which layers composed of materials having different work functions are laminated.

(First Photoactive Layer) The first photoactive layer (photoelectric conversion layer) 103 formed by the method of the embodiment has a perovskite structure in at least a part thereof. The perovskite structure is one of the crystal structures, and refers to the same crystal structure as the perovskite. Typically, the perovskite structure is composed of ions A, B, and X, and may take the perovskite structure when the ion B is smaller than the ion A. A chemical composition of this crystal structure can be represented by the following general Equation (1).

ABX₃ (1)

Here, A may be a primary ammonium ion. Specific examples of A include CH₃NH³⁺ (hereinafter, sometimes referred to as MA), C₂H₅NH³⁺, C₃H₇NH³⁺, C₄H₉NH³⁺, and HC(NH₂)²⁺ (hereinafter, sometimes referred to as FA), and A is preferred but not limited to CH₃NH³⁺. In addition, as A, Cs and 1,1,1-trifluoro-ethylammonium iodide (FEAI) are also preferable, but are not limited thereto. B is a divalent metal ion, and is preferably Pb²⁺ or Sn²⁺, but is not limited thereto. X is preferably a halogen ion. For example, X is selected from F⁻, Cl⁻, Br⁻, I⁻, and At⁻, and is preferred but not limited to Cl⁻, Br⁻, or I⁻. Each of the materials constituting the ions A, B, or X may be a single material or a mixture. The constituent ions can function without necessarily matching with the stoichiometric ratio of ABX₃.

The ion A constituting the perovskite of the first photoactive layer preferably has an atomic weight or a total (molecular weight) of atomic weights constituting the ions of 45 or more. More preferably, the ion A contains ions of 133 or less. Since the ion A under these conditions has low stability alone, a general MA (molecular weight: 32) may be mixed, but when the MA is mixed, the band gap approaches 1.1 eV of silicon, and as a tandem that improves efficiency by wavelength division, the overall characteristics deteriorate. In addition, a refractive index with respect to an optical wavelength is also affected, and the effect of the light scattering layer is reduced. Further, since MA has a small molecular weight, it is preferable to avoid MA because it is gasified to generate voids in the perovskite layer as deterioration progresses, resulting in an unintended combination of light scattering and light scattering layer. When Cs is contained, Cs is more preferably 0.1 to 0.9.

This crystal structure has a unit lattice such as a cubic crystal, a tetragonal crystal, or an orthorhombic crystal, and A is arranged at each vertex, B is arranged at a body center, and X is arranged at each face center of the cubic crystal with B as the center. In this crystal structure, an octahedron composed of one B and six X contained in the unit lattice is easily distorted by interaction with A, and phase transitions to a symmetric crystal. It is presumed that this phase transition dramatically changes the physical properties of the crystal, and electrons or holes are released outside the crystal, resulting in power generation.

When the thickness of the first photoactive layer is increased, the light absorption amount increases and the short circuit current density (Jsc) increases, but loss due to deactivation tends to increase as the carrier transport distance increases. For this reason, there is an optimum thickness in order to obtain the maximum efficiency. Specifically, the thickness of the first photoactive layer is preferably 30 to 1000 nm, and more preferably 60 to 600 nm.

For example, by individually adjusting the thickness of the first photoactive layer, it is also possible to adjust the element according to the embodiment and other general elements to have the same conversion efficiency under the sunlight irradiation condition. However, since the type of photoactive layer is different, the element according to the embodiment can realize higher conversion efficiency than a general element under a low illuminance condition of about 200 lux.

The first photoactive layer can be formed by any method. However, it is preferable to form the first photoactive layer by a coating method from the viewpoint of cost. That is, a coating liquid containing a precursor compound having a perovskite structure and an organic solvent capable of dissolving the precursor compound is applied onto a base, for example, the first doped layer, the intermediate passivation layer, the intermediate transparent electrode, or the second buffer layer, to form a coating film. At this time, the surface of the underlayer with which the first photoactive layer is in contact is substantially a smooth surface. That is, an interlayer interface existing between the first photoactive layer and the adjacent layer on the second photoactive layer side is a substantially smooth surface. When the underlayer has such a shape, the thickness of the first photoactive layer can be made uniform, and formation of a short-circuit structure can be prevented.

As the solvent used for the coating liquid, for example, N,N-dimethylformamide (DMF), γ-butyrolactone, dimethylsulfoxide (DMSO), or the like is used. The solvent is not limited as long as it can dissolve the material, and may be mixed. The first photoactive layer can be formed by applying a single coating liquid in which all the raw materials forming the perovskite structure are dissolved in one solution. In addition, it is also possible to individually dissolve a plurality of raw materials forming the perovskite structure into a plurality of solutions to prepare a plurality of coating liquids, and sequentially apply the plurality of coating liquids. For the application, a spin coater, a slit coater, a bar coater, a dip coater, or the like can be used.

The coating liquid may further contain an additive. As such an additive, 1,8-diiodooctane (DIO) or N-cyclohexyl-2-pyrrolidone (CHP) is preferable.

In general, it is known that when a mesoporous structure is included in an element structure, leakage current between the electrodes is suppressed even when pinholes, cracks, voids, or the like are generated in a photoactive layer. When the element structure does not have the mesoporous structure, it is difficult to obtain such an effect. However, when the coating liquid contains a plurality of raw materials having the perovskite structure in the embodiment, volume shrinkage during active layer formation is small, so that a film having fewer pinholes, cracks, and voids is easily obtained. Further, when methyl ammonium iodide (MAI), a metal halogen compound, and/or the like coexist at the time of forming the perovskite structure, a reaction with an unreacted metal halogen compound proceeds, and a film having further fewer pinholes, cracks, and voids is easily obtained. Therefore, it is preferable to add MAI and/or the like to the coating liquid or to coat a solution containing MAI and/or the like on the coating film after coating.

The coating liquid containing the precursor of the perovskite structure may be applied twice or more. In such a case, since the active layer formed by the first application tends to be a lattice mismatch layer, it is preferable that the active layer is applied so as to have a relatively thin thickness. Specifically, the second and subsequent coating conditions are preferably conditions for reducing the film thickness, such as a relatively high rotation speed of the spin coater, a relatively narrow slit width of the slit coater or the bar coater, a relatively high pulling speed of the dip coater, and a relatively low solute concentration in the coating solution.

After completion of the perovskite structure forming reaction, annealing is preferably performed in order to dry the solvent. Since the annealing is performed to remove the solvent contained in the perovskite layer, it is preferable to perform the annealing before forming a next layer, for example, the buffer layer, on the first photoactive layer. An annealing temperature is 50° C. or higher, more preferably 90° C. or higher; and the upper limit is 200° C. or lower, more preferably 150° C. or lower. It should be noted that when the annealing temperature is low, the solvent may not be sufficiently removed, and when the annealing temperature is too high, the smoothness of the surface of the first photoactive layer may be lost.

When the perovskite layer is formed by coating, a surface that is not a coated surface, for example, a surface of the second electrode may be contaminated. Since the perovskite contains a halogen element having corrosiveness, it is preferable to remove contamination. A method for removing contamination is not particularly limited, but a method for causing ions to collide with the passivation layer, a laser treatment, an etching paste treatment, and solvent cleaning are preferable. The removal of contamination is preferably performed before the first electrode is formed.

(First Buffer Layer and Second Buffer Layer)

In FIG. 1, the first buffer layer 102 and the second buffer layer 104 are layers existing between the first electrode and the first photoactive layer or between the first photoactive layer and the tunnel insulating film, respectively. The first buffer layer 102 and the second buffer layer 104 are layers for preferentially transporting electrons or holes. Here, when the second buffer layer exists, the second buffer layer serves as the underlayer of the first photoactive layer, and therefore, the surface of the second buffer layer is preferably a substantially smooth surface.

The first buffer layer and the second buffer layer may have a laminated structure of two or more layers. For example, the first buffer layer can be a layer containing an organic semiconductor and a layer containing a metal oxide. The layer containing a metal oxide can exhibit a function of protecting the active layer when the first transparent electrode is formed. The first transparent electrode has an effect of suppressing deterioration of the first electrode. In order to sufficiently exhibit such an effect, the first transparent electrode is preferably a layer denser than the first buffer layer.

When the first buffer layer and the second buffer layer exist, one of the first buffer layer and the second buffer layer functions as a hole transport layer, and the other functions as an electron transport layer. In order for the semiconductor element to achieve more excellent conversion efficiency, it is preferable to include these layers, but these layers are not necessarily essential in the embodiment, and either or both of these layers may not be included.

The electron transport layer has a function of efficiently transporting electrons. When the buffer layer functions as an electron transport layer, the layer preferably contains either a halogen compound or a metal oxide. Preferable examples of the halogen compound include LiF, LiCl, LiBr, LiI, NaF, NaCl, NaBr, NaI, KF, KCl, KBr, KI, and CsF. Among them, LiF is particularly preferable.

Preferable examples of the element constituting the metal oxide include titanium, molybdenum, vanadium, zinc, nickel, lithium, potassium, cesium, aluminum, niobium, tin, and barium. A composite oxide containing a plurality of metal elements is also preferable. For example, zinc oxide (AZO) doped with aluminum, titanium oxide doped with niobium, and the like are preferable. In these metal oxides, titanium oxide is more preferable. The titanium oxide is preferably amorphous titanium oxide obtained by hydrolyzing a titanium alkoxide by a sol-gel method.

In addition, an inorganic material such as metallic calcium can also be used for the electron transport layer.

An n-type semiconductor can also be used for the electron transport layer. An n-type organic semiconductor is preferred but not limited to fullerene and a derivative thereof. Specific examples thereof include derivatives having C60, C70, C76, C78, C84, or the like as a basic skeleton. In a fullerene derivative, a carbon atom in a fullerene skeleton may be modified with an arbitrary functional group, and the functional groups may be bonded to each other to form a ring. The fullerene derivative includes fullerene-bonded polymers. The fullerene derivative is preferably a fullerene derivative having a functional group having high affinity for a solvent and having high solubility in a solvent.

Examples of the functional group in the fullerene derivative include a hydrogen atom; a hydroxy group; a halogen atom such as a fluorine atom or a chlorine atom; an alkyl group such as a methyl group or an ethyl group; an alkenyl group such as a vinyl group; a cyano group; an alkoxy group such as a methoxy group or an ethoxy group; an aromatic hydrocarbon group such as a phenyl group or a naphthyl group, an aromatic heterocyclic group such as a thienyl group or a pyridyl group, and the like. Specific examples thereof include a hydrogenated fullerene such as C60H36 and C70H36, an oxide fullerene such as C60 and C70, and a fullerene metal complex.

Among the above, it is particularly preferable to use [60]PCBM([6,6]-phenyl C61 butyric acid methyl ester) or [70]PCBM([6,6]-phenyl C71 butyric acid methyl ester) as the fullerene derivative.

In addition, as the n-type organic semiconductor, a low molecular weight compound that can be deposited by vapor deposition can be used. The low molecular weight compound referred to herein is one in which a number average molecular weight Mn and a weight average molecular weight Mw are the same. Any one of them is 10,000 or less. BCP (2,9-dimethyl-4,7-diphenyl-1,10-phenanthroline), Bphen (4,7-diphenyl-1,10-phenanthroline), TpPyPB (1,3,5-tri(p-pyridin-3-yl-phenyl)benzene), DPPS (diphenyl-bis(4-pyridine-3-yl)phenyl)silane) are more preferred.

When the electron transport layer is provided in the photoelectric conversion element according to the embodiment, a thickness of the electron transport layer is preferably 20 nm or less. This is because a film resistance of the electron transport layer can be lowered and conversion efficiency can be enhanced. Meanwhile, the thickness of the electron transport layer can be 5 nm or more. By providing the electron transport layer and setting the thickness thereof to a certain value or more, hole blocking effects can be sufficiently exhibited, and it is possible to prevent generated excitons from being deactivated before releasing electrons and holes. As a result, the current can be efficiently extracted.

The hole transport layer has a function of efficiently transporting holes. When the buffer layer functions as a hole transport layer, the layer can contain a p-type organic semiconductor material or an n-type organic semiconductor material. The p-type organic semiconductor material and the n-type organic semiconductor material mentioned herein are materials that can function as an electron donor material or an electron acceptor material when a heterojunction or a bulk heterojunction is formed.

The p-type organic semiconductor can be used as a material of the hole transport layer. The p-type organic semiconductor preferably contains, for example, a copolymer composed of a donor unit and an acceptor unit. As the donor unit, fluorene, thiophene, or the like can be used. As the acceptor unit, benzothiadiazole or the like can be used. Specifically, polythiophene and derivatives thereof, polypyrrole and derivatives thereof, pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having an aromatic amine in a side chain or a main chain, polyaniline and derivatives thereof, phthalocyanine derivatives, porphyrin and derivatives thereof, polyphenylenevinylene and derivatives thereof, polythienylenevinylene and derivatives thereof, benzodithiophene derivatives, thieno[3,2-b]thiophene derivatives, and the like can be used. For the hole transport layer, these materials may be used in combination, or a copolymer composed of a copolymer constituting these materials may be used. Among them, polythiophene and derivatives thereof are preferable because they have excellent stereoregularity and have relatively high solubility in a solvent.

In addition, as a material of the hole transport layer, a derivative such as poly[N-9′-heptadecanyl-2,7-carbazole-alto-5,5-(4′,7′-di-2-thienyl-2′,1′,3′-benzothiadiazole)] (hereinafter, sometimes referred to as PCDTBT), which is a copolymer containing carbazole, benzothiadiazole, and thiophene, may be used. Furthermore, a copolymer of a benzodithiophene (BDT) derivative and a thieno[3,2-b]thiophene derivative is also preferable. For example, poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]] (hereinafter sometimes referred to as PTB7), PTB7-Th (sometimes referred to as PCE 10, or PBDTTT-EFT) in which a thienyl group having a weaker electron donating property than the alkoxy group of PTB7 is introduced, and the like are also preferable. Furthermore, a metal oxide can also be used as a material of the hole transport layer. Preferable examples of the metal oxide include titanium oxide, molybdenum oxide, vanadium oxide, zinc oxide, nickel oxide, lithium oxide, calcium oxide, cesium oxide, and aluminum oxide. These materials have the advantage of being inexpensive. Furthermore, as the material of the hole transport layer, a thiocyanate such as copper thiocyanate may be used.

In addition, a dopant can be used for a transport material such as spiro-OMeTAD and the aforesaid p-type organic semiconductor. As the dopant, oxygen, 4-tert-butylpyridine, lithium-bis(trifluoromethanesulfonyl)imide(Li-TFSI), acetonitrile, tris[2-(1H-pyrazole-1yl)pyridine]cobalt(III)tris(hexafluorophosphate) salt (commercially available under the trade name of “FK102”), tris[2-(1H-pyrazole-1yl)pyrimidine]cobalt(III)tris[bis(trifluoromethylsulfonyl)imide](MY11), or the like can be used.

As the hole transport layer, a conductive polymer compound such as polyethylene dioxythiophene can be used. As such a conductive polymer compound, those listed in the electrode section can be used. Also in the hole transport layer, it is possible to combine another material with a polythiophene polymer such as PEDOT to adjust a material having an appropriate work function as hole transport or the like. Here, it is preferable to adjust the work function of the hole transport layer to be lower than a valence band of the active layer.

The first buffer layer is preferably an electron transport layer. Furthermore, the oxide layer is preferably an oxide layer of a metal selected from the group consisting of zinc, titanium, aluminum, tin, and tungsten. The oxide layer may be a composite oxide layer containing two or more kinds of metals. This is because the electrical conductivity is improved by the light soaking effect, and thus the power generated in the active layer can be efficiently extracted. By disposing this layer on the first electrode side of the active layer, light soaking can be performed particularly with UV light.

The first buffer layer preferably has a structure in which a plurality of layers are laminated. In such a case, it is preferable to contain an oxide of the metal. With such a structure, when another kind of metal oxide is newly formed by sputtering, the active layer and the metal oxide adjacent to the active layer are less likely to be damaged by sputtering.

The first buffer layer preferably has a structure including voids. More specifically, a buffer layer having a structure including a deposit of nanoparticles and having voids between the nanoparticles, a structure including a bonded body of nanoparticles and having voids between the bonded nanoparticles, and the like is preferable. When the first buffer layer includes a metal oxide film, the film functions as a barrier layer. The barrier layer is provided between the second electrode and the second buffer layer in order to suppress the corrosion of the second electrode due to the substance penetrating from another layer. Meanwhile, the material constituting the perovskite layer tends to have a high vapor pressure at a high temperature. Therefore, a halogen gas, a hydrogen halide gas, and a methylammonium gas are easily generated in the perovskite layer. When these gases are confined by the barrier layer, the element may be damaged from the inside due to an increase in internal pressure. In such a case, peeling of a layer interface is particularly likely to occur. Therefore, since the second buffer layer contains voids, the increase in the internal pressure is alleviated, and high durability can be provided.

When the first electrode, that is, the metal layer is structurally isolated from the first photoactive layer by the metal oxide film, the first electrode is hardly corroded by the substance penetrating from another layer. In the present embodiment, the first photoactive layer contains the perovskite semiconductor. In general, it is known that, from a photoactive layer containing a perovskite semiconductor, halogen ions such as iodine ions or bromine ions diffuse into the element, and the component reaching the metal electrode causes corrosion. When the metal oxide film exists, it is considered that the diffusion of such a substance can be efficiently blocked. It is preferred that the metal oxide film contains indium tin oxide (ITO), fluorine-doped tin oxide (FTO), and aluminum-doped zinc oxide (AZO). A thickness of the metal oxide film is preferably 5 to 100 nm, and more preferably 10 to 70 nm. With such a structure, a metal oxide similar to the metal oxide generally used for a transparent electrode can be used, but it is preferable to use a metal oxide layer having physical properties different from those of a general metal oxide layer used for a transparent electrode. That is, it is characterized not simply by a simple constituent material, but also by its crystallinity or oxygen content. Qualitatively, the crystallinity or oxygen content of the metal oxide film contained in the first buffer layer is lower than that of a metal oxide layer formed by sputtering, which is generally used as an electrode. Specifically, the oxygen content is preferably 62.1 to 62.3 atom %. Whether the metal oxide film functions as a penetration preventing layer for corrosive substances can be confirmed by elemental analysis in the cross-sectional direction after the durability test. As the analysis means, time-of-flight secondary ion mass spectrometry (TOF-SIMS) or the like can be used. At least two or more peaks of the degraded substance are separately detected so as to sandwich the material exhibiting prevention of penetration of the corrosive substance, and a peak area on the first electrode side is smaller than a total area of the other peaks. When the penetration is completely prevented, the peak on the first electrode side cannot be confirmed. It is preferable that the peak on the first electrode side is so small that it cannot be confirmed, but the durability of the element is greatly improved even when the most part of the peak on the first electrode side is shielded. That is, even when a part of the first electrode is deteriorated, the characteristics such as the overall electrical resistance of the first electrode are not greatly changed, so that a large change does not appear in the conversion efficiency of the solar cell. Meanwhile, when the penetration is not sufficiently prevented and the first electrode and the corrosive substance react with each other, the characteristics such as the electrical resistance of the first electrode greatly change, so that the conversion efficiency of the solar cell greatly changes (the conversion efficiency decreases). Preferably, the method for forming the peak area on the first electrode side is not particularly limited, but may be 0.007 with respect to the total area of the other peaks. Such a metal oxide film can be formed by sputtering under specific conditions.

The metal oxide film can also be formed by a coating method. In order to improve the smoothness of the interface existing between the first photoactive layer and the adjacent layer on the second photoactive layer side, it is preferable to form the film by coating.

(Intermediate Transparent Electrode)

The intermediate transparent electrode 105 electrically connects a top cell and a bottom cell while separating the top cell and the bottom cell from each other, and has a function of guiding light not absorbed by the top cell to the bottom cell. Therefore, the material can be selected from transparent or translucent conductive materials. Such a material can be selected from the same materials as those of the first transparent electrode.

A thickness of the intermediate transparent electrode is preferably 10 nm to 70 nm. When the thickness is less than 10 nm, there are many film defects, and isolation between layers adjacent to the intermediate transparent electrode becomes insufficient. When the thickness is larger than 70 nm, the light transmissivity may cause a decrease in power generation amount of the bottom cell, for example, a silicon cell, due to a diffraction effect.

(First Doped Layer and Second Doped Layer)

In FIG. 1, the first doped layer 106 and the second doped layer 109 are layers disposed between the first photoactive layer 103 and the second photoactive layer 108 or between the second photoactive layer 108 and the second electrode 110, respectively.

As these doped layers, depending on the characteristics of the second photoactive layer, an n-type layer, a p-type layer, a p+-type layer, a p++-type layer, and the like can be combined according to a purpose such as improving carrier collection efficiency. Specifically, when p-type silicon is used as the second photoactive layer, a phosphorus-doped silicon film (n layer) as the first doped layer can be combined with the p+ layer as the second doped layer.

In addition, in the embodiment, the first doped layer is obtained by doping silicon with a trivalent or pentavalent element as an impurity, specifically, phosphorus, arsenic, antimony, boron, aluminum, gallium, or indium. With such a configuration, a tunnel effect in the tunnel insulating film described later can be realized.

The p+ layer, the p++ layer, and the like can be formed by, for example, introducing a necessary dopant into amorphous silicon (a-Si). First, silicon is deposited by a PECVD method or the like to form an a-Si layer, and a part of the a-Si layer is crystallized by an annealing treatment to form a layer having high carrier transportability. Doped amorphous silicon can also be formed by forming a film using silane and diborane, or silane and phosphine as raw materials at a low temperature.

The a-Si layer can also be doped with phosphorus. The method for doping phosphorus is not particularly limited. A phosphorus-containing compound such as POCI3 or PH3 can be used as a dopant supply source. Phosphosilicate glass (PSG) is widely used as a phosphorus diffusion source. More specifically, PSG is deposited on a silicon substrate surface by, for example, utilizing a reaction between POCI3 and oxygen, and then a heat treatment is performed at 800 to 950° C., and phosphorus can be doped into the silicon substrate by thermal diffusion. After the doping treatment, the PSG can also be removed with an acid.

Similarly, the a-Si layer can be doped with boron. The method for doping the boron is not particularly limited. A boron-containing compound such as BBr₃, B2H6, or BN can be used as a dopant supply source. Borosilicate glass (BSG) is widely used as a diffusion source of boron. More specifically, BSG is deposited on a substrate surface by, for example, utilizing a reaction between BBr₃ and oxygen, and then a heat treatment is performed at, for example, 800 to 1000° C., preferably 850 to 950° C., and boron can be doped into the silicon substrate by thermal diffusion. After the doping treatment, the BSG can be removed with an acid.

In addition, a dopant such as phosphorus or boron can be additionally doped using a laser. Such methods can also be utilized for the formation of selective emitters.

In the element of the embodiment, the first doped layer is substantially a smooth surface. Since the first doped layer has a smooth surface, the first doped layer is suitable for forming a perovskite layer thereon with a uniform thickness by coating.

When the element according to the embodiment is considered to be distinguished into the top cell and the bottom cell, the bottom cell corresponds to the silicon solar cell. A general silicon solar cell has a textured structure on the surface, and when such a cell is adopted as the bottom cell, the thickness of a perovskite layer formed thereon becomes uneven, and a short-circuit structure is formed at a portion having a small thickness, thereby deteriorating the characteristics of the solar cell. However, when the textured structure of the surface is eliminated to form a smooth surface, light reflection on the surface decreases, the amount of light taken into the silicon layer having a large refractive index decreases, and as a result, the amount of current decreases. However, in the element according to the embodiment, in a case where the first transparent electrode is provided, since the refractive index thereof is close to the refractive index of the atmosphere, it is possible to increase the amount of light taken in even without the textured structure.

In addition, since the first doped layer has a narrower bandgap due to the effect of doping, the first doped layer tends to absorb light having a longer wavelength. As a result, carriers having a short lifetime tend to be generated in the first doped layer. Therefore, by adopting a substantially uniform layer having a uniform thickness without adopting the textured structure for the first doped layer, it is possible to narrow a carrier generation region to suppress generation of carriers, in other words, carrier loss. As a result, the amount of current to be generated can be increased.

In addition, since the carrier generation region can be further limited by reducing the thickness of the first doped layer, the amount of current to be generated can be further increased. Specifically, the thickness of the first doped layer is preferably 1 to 1000 nm, and more preferably 2 to 4 nm.

(Tunnel Insulating Film)

In the embodiment, an insulating film disposed between the first photoactive layer and the second photoactive layer, preferably between the first doped layer and the second photoactive layer, and having a carrier extraction function from the second photoactive layer is the tunnel insulating film 107. The tunnel insulating film is an insulator because of a large band gap, but when an electric field is applied, carriers are moved from a conduction band of the second photoactive layer to a conduction band of the first doped layer (generally the silicon oxide layer) having semiconductor characteristics by a tunnel effect. The tunnel insulating film passivates the surface of silicon or the first doped layer constituting the second photoactive layer while carrier movement is performed by the tunnel effect, and also contributes to reduction of dangling bonds. Therefore, carrier recombination at the interface is prevented, and photocurrent from silicon can be improved.

A thickness of the tunnel insulating film is 1 nm to 15 nm, and preferably 1 nm to 10 nm. When the thickness is more than 20 nm, the insulating effect is increased to become a resistance component, and the performance of the solar cell is deteriorated. The tunnel current is divided into a Fowler-nordheim tunnel current and a direct tunnel current, but when the tunnel insulating film is thin, a direct tunnel phenomenon occurs.

The material of the tunnel insulating film is not limited, but silicon oxide is preferable. The production method is also not particularly limited, but it is also possible to form the film secondarily at the time of phosphorous doping or form the film by a film forming apparatus such as CVD. It is also convenient and preferable to thermally oxidize the silicon layer. Furthermore, the tunnel insulating film can be formed by chemical treatment, and can be generated by treatment at 400 to 700° C. for 1 to 100 minutes under an atmosphere of HNO₃, O₂, or the like.

Since silicon oxide has a refractive index different from that of silicon, when the silicon oxide film is disposed between the top cell and the bottom cell, the amount of light reaching each cell is affected. However, as long as the thin film can achieve the tunneling effect, it is possible to balance the current values of the respective cells while suppressing the influence on the light amount, and it is possible to avoid a decrease in efficiency as a multilayer junction photoelectric conversion element. In particular, when the film thickness of the tunnel insulating film is too thick, the amount of light incident on the bottom cell decreases, and the current value of the bottom cell may decrease, and thus attention is required.

The tunnel insulating film also functions as a barrier layer that suppresses diffusion of halogen ions and the like. Therefore, the top cell of the second electrode often made of metal is less likely to be corroded by a substance penetrating from another layer, particularly the first photoactive layer containing halogen ions. In a semiconductor element including a perovskite semiconductor, it is known that halogen ions such as iodine and bromine diffuse from an active layer into the element, and a component reaching a metal electrode or the like causes corrosion, but it is considered that diffusion of such a substance can be efficiently blocked.

In addition, the refractive index of the tunnel insulating film is preferably between the refractive index of the atmosphere and the refractive index of silicon. In particular, the refractive index at 630 nm is preferably 1.2 to 2.5, more preferably 1.4 to 2, and most preferably 1.6 or less.

(Second Photoactive Layer)

In FIG. 1, the second photoactive layer 108 contains silicon. A silicon having a configuration similar to that of the silicon generally used for a photovoltaic cell can be adopted as the silicon contained in the second photoactive layer. Specific examples thereof include crystalline silicon containing crystalline silicon such as monocrystalline silicon, polycrystalline silicon, and heterojunction silicon, and thin-film silicon containing amorphous silicon. The silicon may be a thin film cut out from a silicon wafer. As the silicon wafer, an n-type silicon crystal doped with phosphorus or the like and a p-type silicon crystal doped with boron or the like can also be used. The electrons in the p-type silicon crystal have a long diffusion length, and therefore are preferable. A thickness of the second photoactive layer is preferably 100 to 300 μm.

The second photoactive layer may have a uniform thickness, but a texture may be formed on one surface in order to increase the utilization efficiency of the incident light. In a general solar cell or the like, a texture may be formed on the light incident surface side, but in the embodiment, since the light incident surface of the second photoactive layer uses the light transmitted through the top cell, it is preferable to smooth the light incident surface and form a texture on the opposite side surface.

(Second Electrode)

The second electrode 112 can be formed using any conventionally known material as long as it has conductivity. In addition, the method for forming the second electrode 112 is not particularly limited. Specifically, the second electrode 112 can be formed in the same manner as the first metal electrode described above. Further, in FIG. 1, the second electrode 112 has a plurality of electrodes disposed apart from each other on the back surface of the element, but may be formed along the entire back surface of the element. In this case, light that cannot be absorbed by the first and second photoactive layers can be reflected by the second electrode and used again for photoelectric conversion in the first and second photoactive layers.

A thickness of the second electrode is preferably 30 to 300 nm. When the thickness of the electrode is less than 30 nm, conductivity tends to decrease and resistance tends to increase. An increase in resistance may cause a decrease in photoelectric conversion efficiency. A thickness of 100 nm or less is preferable for improving power generation efficiency and light emission efficiency because even a metal has light transmissivity in that thickness. A sheet resistance of the electrode is preferably as low as possible, and is preferably 10 Ω/sq. or less. The electrode may have a single-layer structure or a multilayer structure in which layers made of different materials are laminated.

When the thickness of the second electrode is thinner than the above range, the resistance becomes too large, and the generated charge may not be sufficiently transmitted to the external circuit. When the film thickness is large, it takes a long time to form the electrode, so that the temperature of the material increases, and other materials are damaged, and the performance may be deteriorated. Furthermore, since a large amount of material is used, an occupancy time of a film forming apparatus becomes long, which may lead to an increase in cost.

(Passivation Layer)

The passivation layer 110 is disposed on the outermost surface opposite to the light incident surface in the photoelectric conversion element according to the embodiment illustrated in FIG. 1. This layer is provided to reduce the dangling bond of the surface of the silicon material constituting the second photoactive layer or the second doped layer.

In the embodiment illustrated in FIG. 1, the passivation layer has an opening, and has a structure in which a current is taken out from the element through the opening. Therefore, since the region where the carriers can be moved is limited, the carriers can be efficiently collected.

The material used to form the first passivation film is preferred but not limited to a material capable of reducing the dangling bond on the silicon surface. Specific examples thereof include a silicon oxide film formed by subjecting a surface of a silicon material to a thermal oxidation treatment, and films such as AlOx and SiNx formed by plasma-enhanced chemical vapor deposition (PECVD), plasma-assisted atomic layer deposition (PEALD), and the like. When a silicon oxide film is formed by thermal oxidation, either dry oxidation in which oxidation is performed in an oxygen atmosphere or wet oxidation in which oxidation is performed in a water vapor atmosphere can be used. A wet oxide film is suitable for efficiently obtaining an oxide film having a uniform thickness. In order to obtain a good interface by a thermal oxidation treatment, it is preferable to employ a high oxidation temperature of about 1000° C. Meanwhile, in order to obtain a good interface in a low-temperature process, it is preferable to form a silicon nitride film (SiNx:H) by employing plasma CVD using an NH₃/SiH₄ gas system. The deposited film thus obtained contains a large amount of hydrogen of about 1×10²¹ atoms/cm³. The refractive index and the hydrogen concentration in the film can be controlled by changing the flow ratio between NH₃ and SiH₄ gas. A thickness of the first passivation film is preferably 100 nm to 100 μm.

In the element according to the embodiment, the passivation layer is formed over the entire back surface side of the second photoactive layer, but a part thereof is removed to form an opening. The opening can be formed by removing a part of the passivation layer by, for example, a wet treatment. In addition, in the case of applying and firing a paste composition containing a metal in order to form the second electrode, when the passivation layer is a silicon nitride film, hydrogen contained in the silicon nitride film diffuses into a silicon crystal, and crystal lattice ends are terminated with hydrogen, so that electrical characteristics are improved.

(Third Doped Layer)

The third doped layer 111 is a layer that can be disposed between the second doped layer and the second electrode. The third doped layer is generally formed after partially removing the passivation layer. The third doped layer can be a p+ layer, a p++ layer, or the like depending on the characteristics of the second photoactive layer and the second doped layer. It is preferable to relatively provide a highly doped layer at a portion of the third doped layer electrically connected to the second electrode. With such a configuration, carrier recombination at the interface between the third doped layer and the electrode can be suppressed. A method for forming the highly doped layer is not particularly limited, but the highly doped layer can be formed by a thermal reaction path using BBr₃.

(Antireflection Layer)

In order to increase the amount of light taken in from the outside, an antireflection layer may be provided in the outermost layer of the element, that is, an interface portion with the atmosphere. Such an antireflection film can be formed using a generally known material, for example, SnNx or MgF₂. These materials can be deposited by a PECVD method, a vapor deposition method, or the like. When an antireflection film is provided on the outermost layer of the element, the first electrode and the second electrode need to be electrically connected to the outside in order to extract a current from the element. Therefore, it is preferable to remove a part of the antireflection film so that the antireflection film does not hinder electrical connection. As such a removal method, a wet etching treatment method, a method using an etching paste, a method using a laser, or the like can be used.

(Design of Tandem Structure)

The element illustrated in FIG. 1 is a tandem solar cell including two photoactive layers, and having a structure in which a unit including a photoactive layer containing a perovskite semiconductor is a top cell, and a unit including a photoactive layer containing silicon is a bottom cell, and the two units are connected in series by an intermediate transparent electrode. In general, the band gap of a silicon solar cell is about 1.1 eV, but by combining the silicon solar with a photovoltaic cell containing a perovskite semiconductor having a relatively wide band gap, light in a wider wavelength region can be efficiently absorbed.

In general, an open circuit voltage of a silicon solar cell is 0.6 to 0.75 V, and the open circuit voltage of a perovskite solar cell is 0.9 to 1.3 V. In a tandem solar cell in which these cells are combined, by increasing the power generation amount by the perovskite solar cell, power with a higher voltage than that of the silicon solar cell alone can be obtained. That is, the output obtained by the tandem solar cell can exceed that of a silicon solar cell alone. Since the tandem solar cell is a series circuit of the top cell and the bottom cell, a voltage value close to the sum of the voltage of the top cell and the voltage of the bottom cell is obtained. Meanwhile, the current is limited by the lower current of the top cell and the bottom cell. Therefore, in order to maximize the output of the tandem solar cell, it is preferable to bring the currents of the top cell and the bottom cell close to each other. In general, in order to bring the currents closer, the material of the active layer is selected to change the wavelength range of light to be absorbed, or the thickness of the photoactive layer is adjusted to change the amount of light to be absorbed. Since a silicon solar cell generally has a short circuit current density of about 40 mA/cm² alone, in a tandem solar cell, it is preferable to adjust the current density to about 20 mA/cm² for the top cell and the bottom cell.

(Method for Manufacturing Element)

The multilayer junction photoelectric conversion element according to the embodiment can be manufactured by laminating the above-described layers in an appropriate order. The order of lamination is not particularly limited as long as a desired structure can be obtained; for example, lamination can be performed in the following order.

A method for manufacturing a multilayer junction photoelectric conversion element, the method including the steps of:
(a) forming a second metal electrode on one surface of a silicon wafer constituting a second photoactive layer;
(b) forming a tunnel insulating film on a back surface of the silicon wafer on which a second electrode is formed;
(c) forming a first doped layer on the tunnel insulating film;
(d) forming a first photoactive layer containing perovskite on the first doped layer by a coating method; and
(e) forming a first electrode on the first photoactive layer.

Further, the following step may be combined before the step (a).
(a0) forming a textured structure on one surface of the silicon wafer.

Furthermore, any of the following steps can be combined between the steps (a) and (b).
(a1) forming a textured structure on a surface of the silicon wafer on which the second electrode is to be formed, as necessary;
(a2) forming a second doped layer on a surface of the silicon wafer on which the second electrode is to be formed, as necessary;
(a3) forming a passivation layer on a surface of the silicon wafer on which the second electrode is to be formed or on a second doped layer, as necessary; and
(a4) forming an opening section in the second doped layer to form a third doped layer, as necessary.

Furthermore, any of the following steps can be combined between the steps (c) and (d).
(c1) forming an intermediate transparent electrode on the first doped layer; and
(c2) forming a second buffer layer on the first doped layer or the intermediate transparent electrode.

Forming a second doped layer on the back surface of the silicon wafer on which the first passivation layer is formed.

Further, as necessary, between step (d) and step (e),
(d1) forming a first buffer layer on the first photoactive layer can also be combined.

In the method exemplified here, the bottom cell including the second photoactive layer is formed first, and the top cell including the first photoactive layer is formed later. According to this method, since the step (a) or (c) of heating at a high temperature is performed before the step (d), the first photoactive layer is less likely to be damaged by heat. Moreover, in the case of forming the first electrode by the step (e), heat is applied to the first photoactive layer, but in the case of heating in the step (d), a temperature lower than the temperature to be heated in the step (f) is preferably employed.

Further, in the step (c), the method for forming the tunnel insulating film can be performed by, for example, a vapor deposition treatment such as CVD, a thermal oxidation treatment of the silicon layer, a chemical treatment with an oxidizing agent, or the like, but it is preferable to perform a chemical treatment, specifically, a treatment at 400 to 700° C. for 1 to 100 minutes under an atmosphere of HNO₃, O₂, or the like.

### Example 1

The multilayer junction photoelectric conversion element having the structure illustrated in FIG. 1 is manufactured. First, a tandem solar cell can be produced using an n-type silicon wafer as a bottom cell. A (111) plane can be selectively left by etching the silicon crystal (100) plane. As a result, a pyramidal uneven structure (textured structure) can be formed on the surface. The opposite side surface can be planarized by polishing. The surface on which the textured structure is formed can be doped with boron to form a P⁺ layer as a second doped layer. It can be formed by performing thermal diffusion using BBr₃ as a diffusion source of boron. A passivation layer can be formed on the surface of the second doped layer. The passivation layer can form 10 nm of Al₂O₃ by PEALD. A part of the passivation layer can be removed by an etching treatment. The third doped layer can be formed as a P⁺⁺ layer by thermal diffusion using BBr₃. A metal electrode containing silver as a main component can be formed on the third doped layer by electron beam evaporation as the second electrode to form a hole extraction electrode.

A tunnel insulating film can be formed on the smooth surface of the silicon wafer by performing HNO₃ and heat treatment. The refractive index of the tunnel insulating film is 1.5. As a first doped layer, a phosphorus-doped Si layer can be formed on the tunnel insulating film by PECVD from silane and phosphine. On the first doped layer, an intermediate transparent electrode can be formed as a 20 nm ITO layer by sputtering ITO as a sputtering source.

As the second buffer layer, an alcohol dispersion of NiOx particles can be deposited by spin coating. After the film formation, annealing is performed at 150° C. The first photoactive layer can be formed by applying a precursor solution in which a precursor of Cs_{0.17}FA_{0.83}Pb(Br_{0.17}I_{0.83})₃ is dissolved in a mixed solvent of DMF and DMSO (DMSO is 10 Vol %). After the film formation, annealing is performed at 150° C. for 5 minutes. As the first buffer layer, C60 can be deposited in a thickness of 50 nm by a vapor deposition machine. Further, SnOx is deposited in a thickness of 10 nm by ALD to form a composite film. Next, IZO can be formed as the first transparent electrode by sputtering. Finally, a tandem solar cell can be formed by depositing silver as the first metal electrode using a vapor deposition machine. The light incident on the tandem solar cell passes through the tunnel insulating film to provide light to the silicon. Since recombination can be suppressed by the tunnel insulating film, high conversion efficiency can be obtained.

### Comparative Example 1

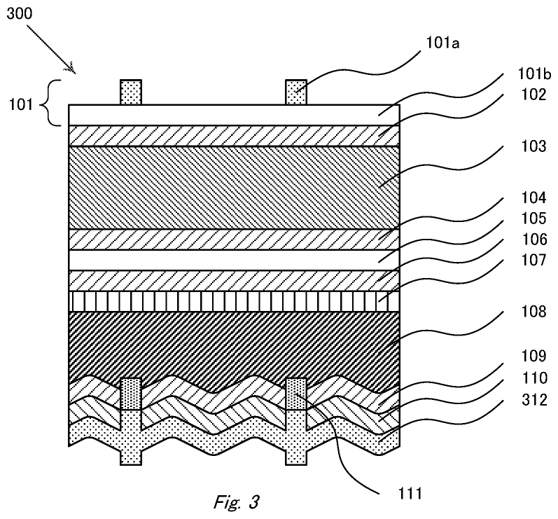

An element having the structure illustrated in FIG. 2 is formed. A silicon oxide film having a thickness of 20 nm can be formed in place of the tunnel insulating film in Example 1. It is difficult to confirm power generation with an undoped silicon oxide film. Power generation can be confirmed by using an n-type doped silicon oxide film as the silicon oxide film. In a case where the thickness of the silicon oxide film is 20 nm, the current of the bottom cell can be increased as compared with a case where the thickness is larger than 20 nm, but, since the light transmittance of the silicon oxide film decreases due to doping, the current amount of the entire tandem is lower than that in Example 1.

### Example 2

An element having the structure illustrated in FIG. 3 is formed. As illustrated in FIG. 3, the second electrode can be provided over a wide range on the passivation layer. As a result, in the light that has passed through the tunnel insulating film and passed through the second photoactive layer, the light that has not been photoelectrically converted can be reflected by the second electrode and provided again to the photoelectric conversion in the photoactive layer.

### REFERENCE SIGNS LIST

100 multilayer junction photoelectric conversion element (multilayer junction photoelectric conversion element of Example 1)
101 first electrode
101a first metal electrode
101b first transparent electrode
102 first buffer layer
103 first photoactive layer including perovskite semiconductor
104 second buffer layer
105 intermediate transparent electrode
106 doped layer having semiconductor characteristics (first doped layer)
107 tunnel insulating film
108 second photoactive layer containing silicon
109 second doped layer
110 passivation film
111 third doped layer
112 second electrode
200 multilayer junction photoelectric conversion element of Comparative Example 1
207 silicon insulating film
300 multilayer junction photoelectric conversion element of Example 2
312 second electrode

1. A multilayer junction photoelectric conversion element comprising:
a first electrode;
a first photoactive layer including a perovskite semiconductor;
a first doped layer;
a tunnel insulating film;
a second photoactive layer containing silicon; and
a second electrode,
in this order,
wherein a thickness of the tunnel insulating film is 1 nm to 15 nm, and
the first doped layer contains silicon and a trivalent or pentavalent element as an impurity.

2. The multilayer junction photoelectric conversion element according to claim 1, wherein the tunnel insulating film is silicon oxide.

3. The multilayer junction photoelectric conversion element according to claim 1, wherein the tunnel insulating film has a refractive index of 1.4 to 2.

4. The multilayer junction photoelectric conversion element according to claim 1, wherein the impurity is phosphorus.

5. The multilayer junction photoelectric conversion element according to claim 1, further comprising a hole transporting buffer layer between the first doped layer and the first photoactive layer.

6. The multilayer junction photoelectric conversion element according to claim 1 further comprising an intermediate transparent electrode between the first doped layer and the first photoactive layer.

7. The multilayer junction photoelectric conversion element according to claim 1, further comprising a second doped layer between the second photoactive layer and the second metal electrode.

8. A method for manufacturing a multilayer junction photoelectric conversion element, the method comprising the steps of:
(a) forming a second metal electrode on one surface of a silicon wafer constituting a second photoactive layer;
(b) forming a tunnel insulating film on a back surface of the silicon wafer on which a second electrode is formed;
(c) forming a first doped layer on the tunnel insulating film;
(d) forming a first photoactive layer containing perovskite on the first doped layer by a coating method; and
(e) forming a first electrode on the first photoactive layer.

9. The method for manufacturing a multilayer junction photoelectric conversion element according to claim 8, wherein a temperature in the step (e) is lower than a temperature in the step (d).

10. The method for manufacturing a multilayer junction photoelectric conversion element according to claim 8, wherein in the step (c), the tunnel insulating film is formed by a chemical treatment.
